(19) United States
(12) Patent Application Publication
(10) Pub. No.: US 2024/0186165 A1
(43) Pub. Date: Jun. 6, 2024

(54) WAFER PICKING AND PLACING APPARATUS

(71) Applicant: HERMES-EPITEK CORPORATION, Taipei City (TW)

(72) Inventors: Cheng-Huang Kuo, Tainan City (TW); Kuo-Meng Lo, Miaoli County (TW); Yu-Cheng Chang, Hsinchu County (TW); Cheng Chang Tseng, Kaohsiung City (TW)

(73) Assignee: HERMES-EPITEK CORPORATION, Taipei City (TW)

(21) Appl. No.: 18/299,019

(22) Filed: Apr. 11, 2023

(30) Foreign Application Priority Data
Dec. 6, 2022 (TW) 111146675

(51) Int. Cl. H01L 21/677; H01L 21/68; H01L 21/683; H01L 21/687

(52) U.S. Cl. CPC H01L 21/67706; H01L 21/67718; H01L 21/6773; H01L 21/67796; H01L 21/68; H01L 21/6838; H01L 21/68764

(57) ABSTRACT

A wafer picking and placing apparatus includes a platform and a hooking unit. The platform is adapted to support a wafer. The hooking unit includes a driving device and a hooking structure, and the hooking structure is connected to the driving device and has at least one hooking end. The driving device is adapted to drive the hooking structure to move between a first position and a second position in a horizontal direction. The driving device is adapted to drive the hooking structure to move between the second position and a third position above the second position in a vertical direction. When the hooking structure is located at the first position, the hooking end is away from the platform. When the hooking structure is located at the second position, the hooking end inserts between a lower side of an edge of the wafer and the platform to hook the wafer.

### CROSS-REFERENCE TO RELATED APPLICATION

This application claims the priority benefit of Taiwan application serial no. 111146675, filed on Dec. 6, 2022. The entirety of the above-mentioned patent application is hereby incorporated by reference herein and made a part of this specification.

### BACKGROUND

### Technical Field

The disclosure relates to a picking and placing apparatus, and in particular, relates to a wafer picking and placing apparatus.

### Description of Related Art

During the manufacturing process, wafers need to be transported and picked and placed to switch among processing/storage procedures at different stages. In order to prevent the wafers from being damaged or contaminated during the picking and placing process, the picking and placing of wafers may be performed through automated apparatuses. However, in the current technology, apparatuses with complex mechanisms and/or high costs are employed most of the time for wafer picking and placing, but such employment is not economical.

### SUMMARY

The disclosure provides a wafer picking and placing apparatus capable of efficiently picking and placing a wafer with a simple structure.

The disclosure provides a wafer picking and placing apparatus including a platform and a hooking unit. The platform is adapted to support a wafer. The hooking unit includes a driving device and a hooking structure, and the hooking structure is connected to the driving device and has at least one hooking end. The driving device is adapted to drive the hooking structure to move between a first position and a second position in a horizontal direction. The driving device is adapted to drive the hooking structure to move between the second position and a third position above the second position in a vertical direction. When the hooking structure is located at the first position, the hooking end is away from the platform. When the hooking structure is located at the second position, the hooking end inserts between a lower side of an edge of the wafer and the platform to hook the wafer. When the hooking structure is located at the third position, the edge of the wafer is lifted by the hooking end so that the wafer is inclined to the platform.

In an embodiment of the disclosure, the edge of the wafer includes a straight edge, the at least one hooking end includes a plurality of hooking ends, and these hooking ends are adapted to hook the wafer together on the straight edge.

In an embodiment of the disclosure, the edge of the wafer includes a notch, the at least one hooking end includes a single hooking end, and the single hooking end is adapted to hook the wafer in the notch.

In an embodiment of the disclosure, the wafer picking and placing apparatus further includes a holding device. The holding device is adapted to hold the wafer and is adapted to rotate between an inclined state and a horizontal state. An angle of inclination of the holding device in the inclined state is the same as an angle of inclination of the wafer inclined to the platform.

In an embodiment of the disclosure, the wafer picking and placing apparatus further includes a transportation unit. The transportation unit is adapted to transport the holding device and the wafer held by the holding device between the platform and a fourth position.

In an embodiment of the disclosure, the wafer picking and placing apparatus further includes a calibration unit. The calibration unit is located at the fourth position and is adapted to support the wafer, and the calibration unit is adapted to calibrate a rotation orientation of the wafer by making the wafer rotate around a vertical axis as a rotation axis.

In an embodiment of the disclosure, the holding device has at least one vacuum suction portion, and the at least one vacuum suction portion is adapted to vacuum suck the wafer.

In an embodiment of the disclosure, the hooking unit includes a sensing component, and the sensing component is connected to the hooking structure and is adapted to sense whether the at least one hooking end hooks the wafer.

To sum up, in the wafer picking and placing apparatus provided by the disclosure, the hooking structure is used to hook the edge of the wafer, and the driving device is used to drive the hooking structure to be lifted and lowered, so that the edge of the wafer is lifted and lowered accordingly. In this way, during the process of picking up the wafer from the platform, the wafer that is lifted and inclined by the hooking end of the hooking structure can be easily held by the holding device. Further, during the process of placing the wafer on the platform, the holding device can first make the edge of the wafer lean against the hooking end of the hooking structure and then make the wafer be placed on the platform smoothly as the hooking structure is lowered. It thus can be seen that the wafer picking and placing apparatus provided by the disclosure can efficiently pick and place wafers with a simple structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1F are schematic diagrams of an operation flow of some components of a wafer picking and placing apparatus according to an embodiment of the disclosure.

FIG. 2 is an enlargement view of a wafer and a hooking end of FIG. 1A.

FIG. 3A is a schematic top view illustrating the wafer and a hooking structure of FIG. 1B.

FIG. 3B is a schematic top view of a wafer and a hooking structure according to another embodiment of the disclosure.

FIG. 4 is a schematic rear view of a holding device and the wafer of FIG. 1F.

FIG. 5A to FIG. 5C are schematic diagrams of the operation flow of some components of the wafer picking and placing apparatus according to an embodiment of the disclosure.

### DESCRIPTION OF THE EMBODIMENTS

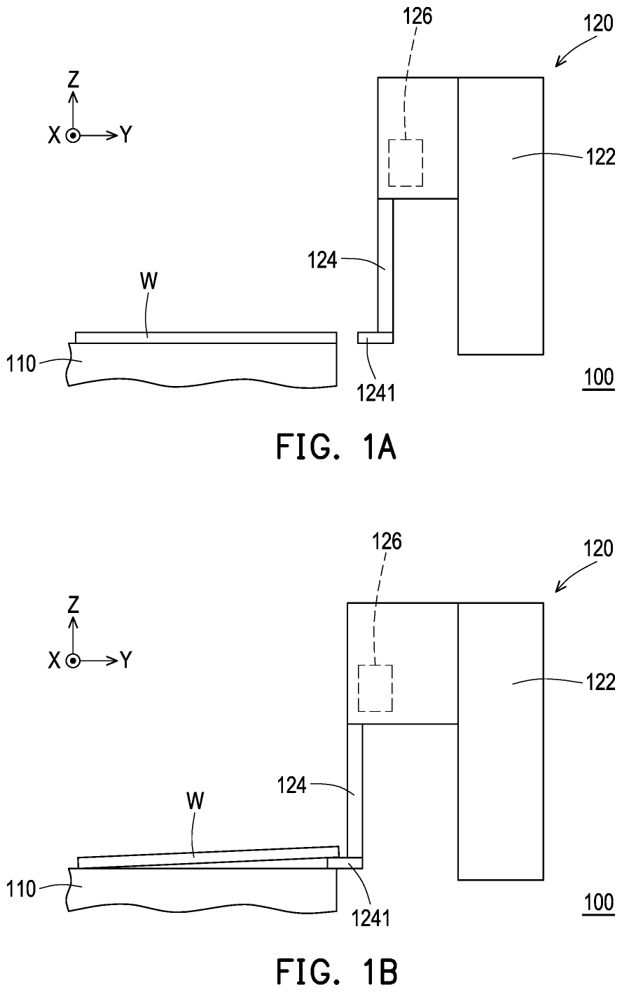

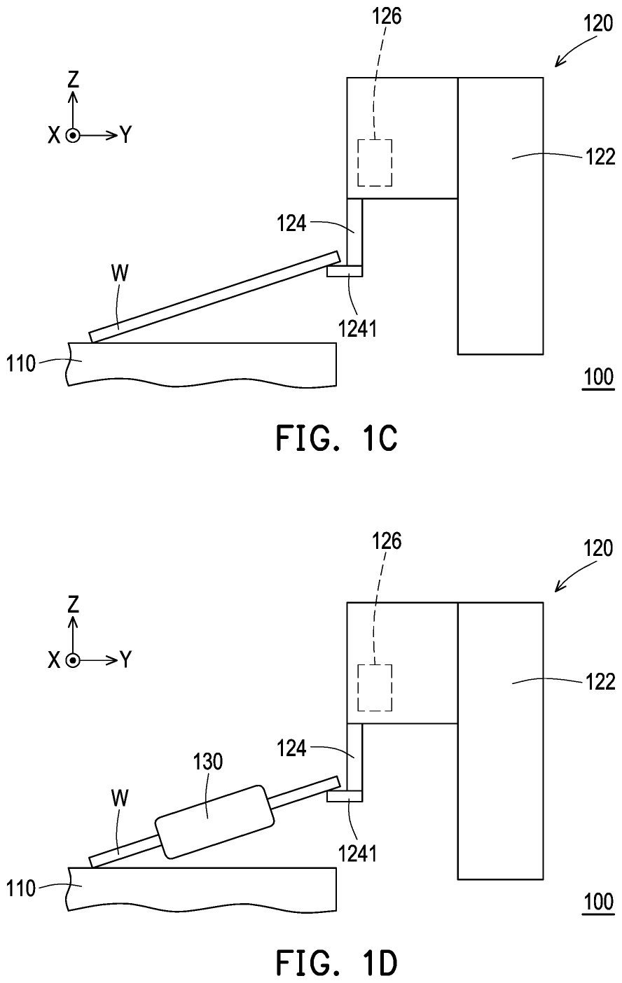

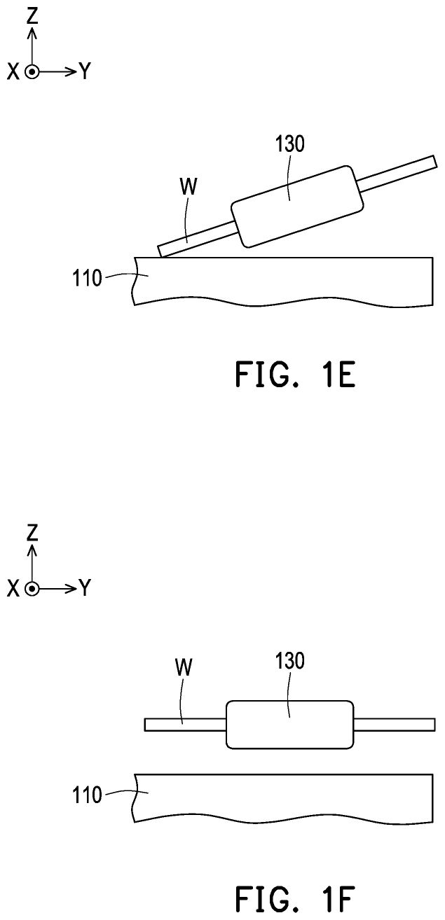

FIG. 1A to FIG. 1F are schematic diagrams of an operation flow of some components of a wafer picking and placing apparatus according to an embodiment of the disclosure, in which axes X, Y, and Z. are illustrated. To make the figures clearer, the drawing of a hooking unit 120 is omitted in FIG. 1E and FIG. 1F. With reference to FIG. 1A, in this embodiment, a wafer picking and placing apparatus 100 includes a platform 110 and the hooking unit 120. The platform 110 is adapted to support a wafer W. The hooking unit 120 includes a driving device 122 and a hooking structure 124, and the hooking structure 124 is connected to the driving device 122 and has at least one hooking end 1241.

The driving device 122 is adapted to drive the hooking structure 124 to move between a first position shown in FIG. 1A and a second position shown in FIG. 1B in a horizontal direction (a direction parallel to the axis Y). Further, the driving device 122 is adapted to drive the hooking structure 1245 to move between the second position shown in FIG. 1B and a third position shown in FIG. 1C above the second position in a vertical direction (a direction parallel to the axis Z). The driving device 122 may include a driving source such as a motor, a cylinder, etc. to perform the abovementioned driving, and the disclosure is not limited thereto.

When the hooking structure 124 is located at the first position as shown in FIG. 1A, the hooking end 1241 of the hooking structure 124 is away from the platform 110. When the hooking structure 124 is located at the second position as shown in FIG. 1B, the hooking end 1241 of the hooking structure 124 inserts between a lower side of an edge of the wafer W and the platform 110 to hook the wafer W. When the hooking structure 124 is located at the third position as shown in FIG. 1C, the edge of the wafer W is lifted by the hooking end 1241 of the hooking structure 124 so that the wafer W is inclined to the platform 110.

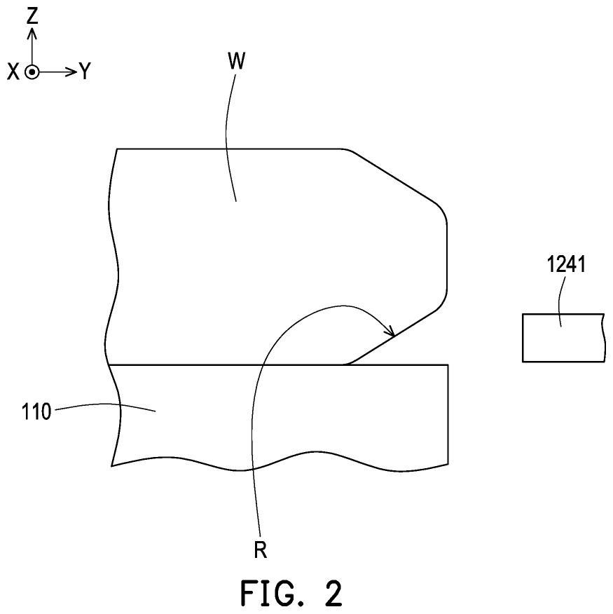

FIG. 2 is an enlargement view of a wafer and a hooking end of FIG. 1A. The wafer W and the hooking end 1241 of FIG. 1A are schematic only. The edge of the wafer W, as shown in FIG. 2, is actually chamfered or rounded to form a guiding slope R. The hooking end 1241 corresponds to the guiding slope R and can be guided by the guiding slope R to smoothly insert between the lower side of the edge of the wafer W and the platform 110 as described above.

In this embodiment, the hooking unit 120 further includes a sensing component 126 (shown in FIG. 1A), and the sensing component 126 is connected to the hooking structure 124 and is adapted to sense whether the hooking end 1241 hooks the wafer W. For instance, the sensing component 126 may include a sensor and a motor coupling assembly, and the motor coupling assembly is connected between the sensor and the hooking structure 124. The displacement of the motor coupling assembly generated when the hooking end 1241 hooks the wafer W makes the sensor detect that the displacement applied by the motor coupling assembly increases, so that it is known that the hooking end 1241 has hooked the wafer W. In other embodiments, the sensing component 126 can sense whether the hooking end 1241 hooks the wafer W through other methods, and the disclosure is not limited thereto.

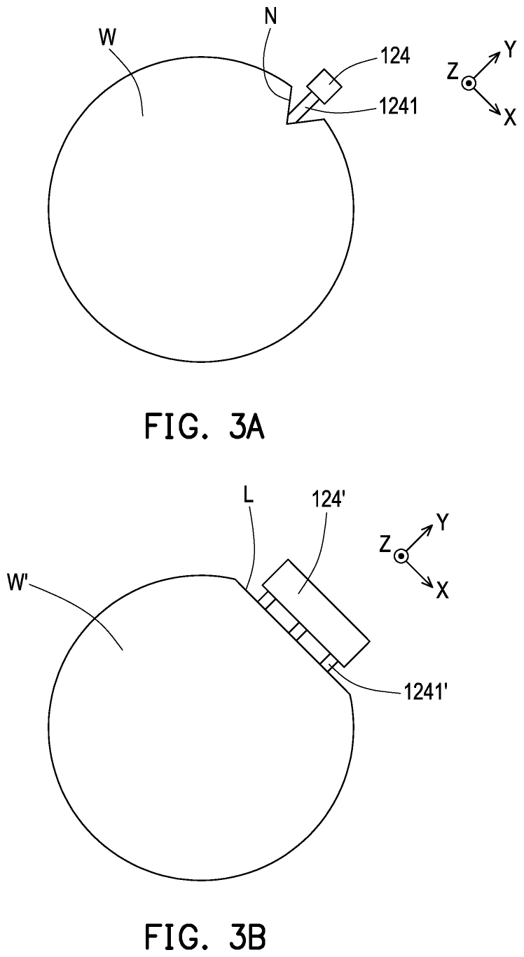

FIG. 3A is a schematic top view illustrating the wafer and a hooking structure of FIG. 1B. FIG. 3B is a schematic top view of a wafer and a hooking structure according to another embodiment of the disclosure. In the embodiment shown in FIG. 3A, the edge of the wafer W has a notch N, and the notch N is, for example, an existing structure of the wafer W to determine its lattice direction. The hooking structure 124 only has a single hooking end 1241, and the single hooking end 1241 is adapted to hook the wafer W in the notch N. In other embodiments, the hooking structure may have a greater number of hooking ends. For instance, in the embodiment shown in FIG. 3B, an edge of a wafer W′ includes a straight edge L, and the straight edge L is, for example, an existing structure of the wafer W′ to determine its lattice direction. A hooking structure 124′ has a plurality of hooking ends 1241′ (three are shown), and these hooking ends 1241′ are adapted to hook the wafer W′ on the straight edge L together.

The wafer picking and placing apparatus 100 provided in the foregoing embodiments further includes a holding device 130 as shown in FIG. 1D. The holding device 130 is adapted to hold the wafer W and is adapted to rotate between an inclined state shown in FIG. 1E and a horizontal state shown in FIG. 1F. As shown in FIG. 1D and FIG. 1E, an angle of inclination of the holding device 130 in the inclined state is the same as an angle of inclination of the wafer W inclined to the platform 110, so that the holding device 130 can hold the inclined wafer W smoothly. The holding device 130 can be driven by a suitable driving source (such as a motor or a cylinder) to rotate as described above, and the disclosure is not limited thereto. Further, the angle of inclination of the wafer W is related to a lifting height of the hooking structure 124. The wafer picking and placing apparatus 100 can calculate the angle of inclination of the wafer W according to the lifting height of the hooking structure 124, so as to control the rotation of the holding device 130 to have the same angle of inclination. The calculation of the angle of inclination of the wafer W is the application of conventional trigonometric functions, and description thereof is not provided herein.

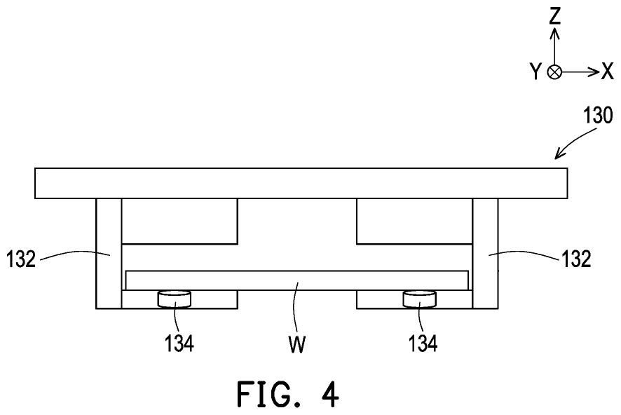

FIG. 4 is a schematic rear view of a holding device and the wafer of FIG. 1F. With reference to FIG. 4, in this embodiment, the holding device 130 holds the wafer W by means of its two holding portions 132, for example. Besides, the holding device 130 may further have a vacuum suction portion 134. The vacuum suction portion 134 is adapted to vacuum suck the wafer W to position the wafer W, so that the holding device 130 may hold the wafer W firmly. The holding device 130 can be driven by a suitable driving source (such as a motor or an cylinder) to hold the wafer W or keep itself away from the wafer W as described above, and the disclosure is not limited thereto.

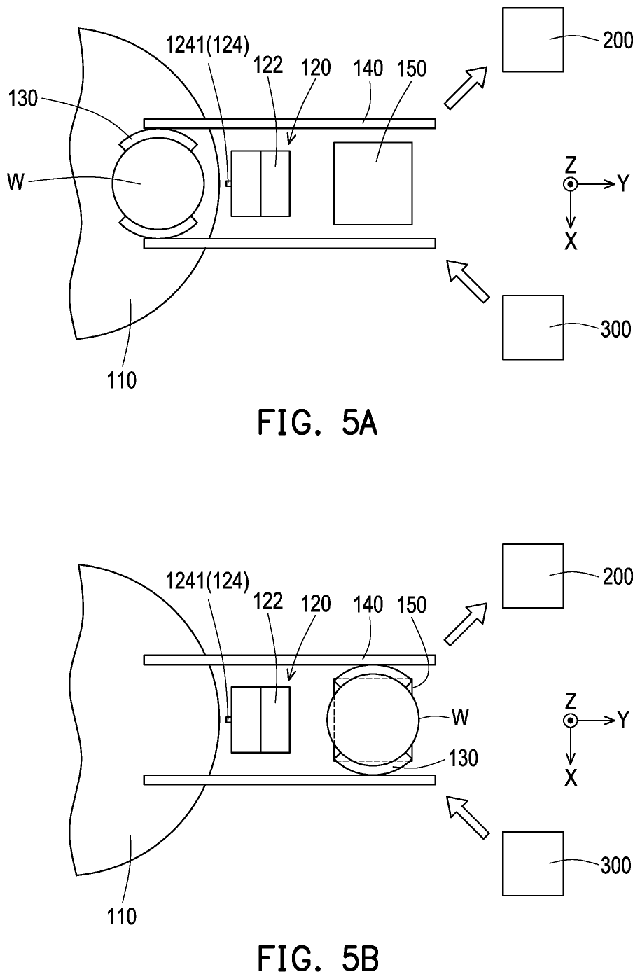

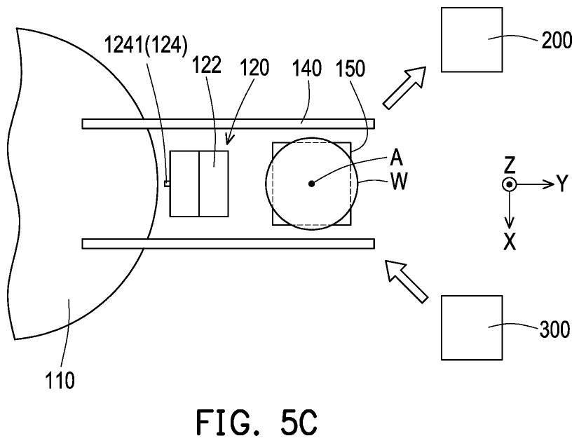

FIG. 5A to FIG. 5C are schematic diagrams of the operation flow of some components of the wafer picking and placing apparatus according to an embodiment of the disclosure, which are the flow processes following FIG. 1F, for example. The wafer W shown in FIG. 5A to FIG. 5C is only schematic. The wafer may actually have a notch N as in wafer W of FIG. 3A or may have a straight edge L as in wafer W′ of FIG. 3B. With reference to FIG. 5A, in this embodiment, the wafer picking and placing apparatus 100 further includes a transportation unit 140 and a calibration unit 150. The transportation unit 140 is located above the hooking unit 120 in the vertical direction (the direction parallel to the axis Z), for example. The holding device 130 in FIG. 1F can be lifted in the vertical direction (the direction parallel to the axis Z) to reach the left end of the transportation unit 140 in FIG. 5A. The holding device 130 can be driven by a suitable driving source (such as a motor or a cylinder) to be lifted as described above, and the disclosure is not limited thereto. The transportation unit 140 is, for example, a track, a transportation belt, or other suitable forms and is adapted to transport the holding device 130 and the wafer W held by the holding device 130 between the platform 110 and a fourth position where the calibration unit 150 is located. In other embodiments, a robotic arm may be used instead to transport the wafer W from the platform to the calibration unit 150, and the arrangement of the holding device 130 and the transportation unit 140 may thus be omitted, but the disclosure is not limited thereto. The calibration unit 150 is adapted to support the wafer W as shown in FIG. 5C and is adapted to calibrate a rotation orientation of the wafer W by making the wafer W rotate around a vertical axis A as a rotation axis. To be specific, the calibration unit 150 may, for example, drive the wafer W to rotate around the vertical axis A as its rotation axis, so as to calibrate the rotation orientation thereof.

The wafer W at the calibration unit 150 may be transported to a wafer storage area 200 for storage by a robotic arm or other appropriate transportation methods. Further, the wafer W stored in the wafer storage area 300 can be transported to the calibration unit 150 by a robotic arm or other suitable transportation methods.

The process of transporting the wafer W from the platform 110 to the wafer storage area 200 by the wafer picking and placing apparatus 100 of the foregoing embodiments is described in detail as follows. First, after the processed wafer W is placed on the platform 110, the hooking end 1241 of the hooking structure 124 inserts between the wafer W and the platform 110 as shown in FIG. 1A to FIG. 1B. As shown in FIG. 1B to FIG. 1C, the wafer W is lifted through the hooking structure 124, so that the wafer W is inclined. As shown in FIG. 1D, the wafer W is held by the holding device 130, the hooking structure 124 is moved away from the wafer W as shown in FIG. 1E, and the holding device 130 is rotated to the horizontal state as shown in FIG. 1F. Next, as shown in FIG. 5A to FIG. 5B, the holding device 130 on the platform 110 and the wafer W held by the holding device 130 are transported to the calibration unit 150 by the transportation unit 140. The holding device 130 is moved away from the wafer W as shown in FIG. 5C. Moreover, the rotation orientation of the wafer W is calibrated by the calibration unit 150, so that the wafer W has an expected rotation orientation based on its own lattice orientation. Next, the wafer W at the calibration unit 150 is transported to the wafer storage area 200 for storage.

The process of transporting the wafer W from the wafer storage area 300 to the platform 110 by the wafer picking and placing apparatus 100 of the foregoing embodiments is described in detail as follows, which is roughly the reverse operation of the foregoing process. First, the wafer W stored in the wafer storage area 300 is transported to the calibration unit 150. The rotation orientation of the wafer W is calibrated by the calibration unit 150, so that the wafer W has an expected rotation orientation based on its own lattice orientation. The holding device 130 at the calibration unit 150 and the wafer W held by the holding device 130 are transported to the platform 110 by the transportation unit 140. The holding device 130 and the wafer W held by the holding device 130 are inclined to make the edge of the wafer W lean against the hooking end 1241 of the hooking structure 124 (as shown in FIG. 1D). The holding device 130 is moved away from the wafer W (as shown in FIG. 1C). The hooking structure 124 is lowered, so that the edge of the wafer W is accordingly lowered (as shown in FIG. 1B). The hooking structure 124 is moved away from the wafer W (as shown in FIG. 1A), so that the wafer W is placed on the platform 110. Next, the wafer W on the platform 110 may be transported to another place for processing.

In view of the foregoing, in the wafer picking and placing apparatus provided by the disclosure, the hooking structure is used to hook the edge of the wafer, and the driving device is used to drive the hooking structure to be lifted and lowered, so that the edge of the wafer is lifted and lowered accordingly. In this way, during the process of picking up the wafer from the platform, the wafer that is lifted and inclined by the hooking end of the hooking structure can be easily held by the holding device. Further, during the process of placing the wafer on the platform, the holding device can first make the edge of the wafer lean against the hooking end of the hooking structure and then make the wafer be placed on the platform smoothly as the hooking structure is lowered. It thus can be seen that the wafer picking and placing apparatus provided by the disclosure can efficiently pick and place wafers with a simple structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A wafer picking and placing apparatus, comprising:
a platform adapted to support a wafer; and
a hooking unit comprising a driving device and a hooking structure, wherein the hooking structure is connected to the driving device and has at least one hooking end,
the driving device is adapted to drive the hooking structure to move between a first position and a second position in a horizontal direction, and the driving device is adapted to drive the hooking structure to move between the second position and a third position above the second position in a vertical direction,
when the hooking structure is located at the first position, the at least one hooking end is away from the platform,
when the hooking structure is located at the second position, the at least one hooking end inserts between a lower side of an edge of the wafer and the platform to hook the wafer,
when the hooking structure is located at the third position, the edge of the wafer is lifted by the at least one hooking end so that the wafer is inclined to the platform.

2. The wafer picking and placing apparatus according to claim 1, wherein the edge of the wafer comprises a straight edge, the at least one hooking end comprises a plurality of hooking ends, and these hooking ends are adapted to hook the wafer together on the straight edge.

3. The wafer picking and placing apparatus according to claim 1, wherein the edge of the wafer comprises a notch, the at least one hooking end comprises a single hooking end, and the single hooking end is adapted to hook the wafer in the notch.

4. The wafer picking and placing apparatus according to claim 1, further comprising a holding device, wherein the holding device is adapted to hold the wafer and is adapted to rotate between an inclined state and a horizontal state, and an angle of inclination of the holding device in the inclined state is the same as an angle of inclination of the wafer inclined to the platform.

5. The wafer picking and placing apparatus according to claim 4, further comprising a transportation unit, wherein the transportation unit is adapted to transport the holding device and the wafer held by the holding device between the platform and a fourth position.

6. The wafer picking and placing apparatus according to claim 5, further comprising a calibration unit, wherein the calibration unit is located at the fourth position and is adapted to support the wafer, and the calibration unit is adapted to calibrate a rotation orientation of the wafer by making the wafer rotate around a vertical axis as a rotation axis.

7. The wafer picking and placing apparatus according to claim 4, wherein the holding device has at least one vacuum suction portion, and the at least one vacuum suction portion is adapted to vacuum suck the wafer.

8. The wafer picking and placing apparatus according to claim 1, wherein the hooking unit comprises a sensing component, and the sensing component is connected to the hooking structure and is adapted to sense whether the at least one hooking end hooks the wafer.
